(19) United States
(12) Patent Application Publication
(10) Pub. No.: US 2004/0192058 A1
(43) Pub. Date: Sep. 30, 2004

(54) Pre-etching plasma treatment to form dual damascene with improved profile

(75) Inventors: Yin-Shen Chu, Taichung (TW); Yi-Chen Huang, Hsinchu (TW); Ching-Hui Ma, Tainan (TW); Jun-Lung Huang, Hsinchu (TW); Hung-Ming Chen, Tainan (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/402,560

(22) Filed: Mar. 28, 2003

(51) Int. Cl. H01L 21/302; H01L 21/461

(52) U.S. Cl. 438/710

(57) ABSTRACT

A method for plasma etching a semiconductor feature to improve an etching profile including providing a semiconductor wafer including a photoresist layer having a photolithographically patterned portion for etching a feature through a thickness portion of at least one underlying dielectric layer; and, plasma treating the photoresist layer with a carbon monoxide (CO) containing plasma to induce a polymeric cross-linking reaction at the photoresist layer surface to decrease a photoresist layer etching rate in a subsequent etching process; and, etching said feature through the thickness portion to maintain a width dimension of said feature including the photolithographically patterned portion within a pre-determined dimensional variation.

### FIELD OF THE INVENTION

This invention generally relates to multi-layered semiconductor structures and more particularly to a method for forming a dual damascene structure with improved via and trench profiles to improve critical dimension bias and to improve metal filling characteristics.

### BACKGROUND OF THE INVENTION

The escalating requirements for high density and performance associated with ultra large scale integration semiconductor wiring require increasingly sophisticated interconnection technology. As device sizes decrease it has been increasingly difficult to provide interconnection technology that satisfies the requirements of low resistance and capacitance interconnect properties, particularly where submicron inter-layer interconnects and intra-layer interconnects have increasingly high aspect ratios (e.g., an interconnect opening depth to diameter ratio of greater than about 4). In particular, high aspect ratio vias require uniform etching profiles including preventing formation of unetched residues around the via openings during anisotropic etching of an overlying trench structure in a dual damascene formation process.

In the fabrication of semiconductor devices, increased device density requires multiple layers, making necessary the provision of a multi-layered interconnect structure. Such a multi-layered interconnect structure typically includes intra-layer conductive interconnects and inter-layer conductive interconnects formed by anisotropically etched openings in an dielectric insulating layer, often referred to as an inter-metal dielectric (IMD) layer, which are subsequently filled with metal. Commonly used inter-layer high aspect ratio openings are commonly referred to as vias, for example, when the opening extends through an insulating layer between two conductive layers. The intra-layer interconnects extending horizontally in the IMD layer to interconnect different areas within an IMD layer are often referred to as trench lines. In one manufacturing approach, trench lines are formed overlying and encompassing one or more vias to form metal inlaid interconnects referred to as dual damascene structures.

In a typical process for forming multiple layer interconnect structures, for example, a dual damascene process, via openings are first anisotropically etched through one or more IMD layers by conventional photolithographic and etching techniques. A second anisotropically etched opening referred to as a trench opening is then formed according to a second photolithographic patterning process overlying and encompassing one or more of the via openings. The via openings and the trench line together makeup the dual damascene structure which is subsequently filled with metal, for example, copper, followed by a CMP planarization process to planarize the wafer process surface and prepare the process surface for formation of another overlying layer or level in a multi-layered semiconductor device.

One approach to increasing signal transport speeds has been to reduce the dielectric constant of the dielectric insulating material used to form IMD layers thereby reducing the capacitance contribution of the IMD layer. Typical low-k (low dielectric constant) materials in use have included carbon doped silicon dioxide and other materials which tend to form a porous material thereby reducing the overall dielectric constant. Porous low-k materials have several drawbacks including enhanced absorption of chemical species including enhanced interaction with photoresist.

One recurring problem affecting the anisotropic etching of sub-micron dual damascene features, particularly with respect to the trench portion etching process has been thought in the prior art to be related to the use of photoresist, including DUV photoresist which includes photoacid generators, to pattern the trench portion for etching. For example, photoresist residue also referred to as scum frequently forms on the sidewalls of the via following the trench photo-patterning process and prior to the trench etching process. The photoresist scum remaining on via sidewalls and degrades subsequent etching profiles of the completed dual damascene structure, for example, leading to via fences. The cause of the photoresist residue has been attributed to interference by residual nitrogen-containing species, for example amines, remaining in an IMD layer with the DUV photoresist. The photoresist residue is also believed to be related to incomplete photo-exposure of the photoresist within the via opening during the trench photo-patterning process. For example, residual nitrogen-containing species contamination originating from amine containing CVD precursors used to deposit nitride etching stop layers and anti-reflectance coating (ARC) layers are believed to play a role in interfering with the photoresist by neutralizing a photogenerated acid catalyst within the photoresist which thereby renders the contaminated portion of the photoresist insoluble in the developer. Regardless of the precise cause of such photoresist residue, the residue frequently remains on via sidewalls detrimentally affecting subsequent etching profiles. For example, during anisotropic etching of a trench opening overlying one or more vias, residual photoresist interacting with the IMD layer at the via sidewall produces an etching resistant residue surrounding the via opening following trench etching. The via fence detrimentally affects subsequent processes, for example, reducing adhesion of deposited overlayers, for example barrier layers and metal filling layers which degrades electrical performance and device reliability.

For example, referring to FIG. 1 is shown a dual damascene structure following trench etching which shows conductive layer 12, etching stop layer 14A, IMD layer 16A, etching stop layer 14B IMD layer 16B and photoresist layer 18. For example via portion 20A is first formed by a first conventional photolithographic patterning and etching process followed by formation of an overlying trench portion 20B by a similar second photolithographic patterning and etching process patterning a trench etching pattern in overlying photoresist layer 18. Following trench etching, an etching resistant via fence, e.g., 22 is formed surrounding the via opening. The via fence is difficult to remove by conventional plasma assisted etching and wet stripping processes and leads to subsequent device degradation and unreliability be adversely affecting the adhesion of subsequent overlayers, for example barrier layers and metal filling layers. Moreover, according to prior art trench etching processes the trench profile tends to be enlarged due to etching of an upper portion e.g., 18A of overlying patterned photoresist layer 18 due to an undesirably low etching selectivity of the IMD layer with respect to the photoresist layer which results in variation of the trench width critical dimension (CD).

There is therefore a need in the semiconductor processing art to develop a method for reliably etch dual damascene structures with improved critical dimension bias and to avoid forming etching resistant residues that detrimentally affect etching profiles and degrade device reliability and electrical performance.

It is therefore an object of the invention to provide a method for reliably etch dual damascene structures with improved critical dimension bias and improved etching profiles while avoiding forming etching resistant residues that detrimentally affect etching profiles and degrade device reliability while overcoming other shortcomings and deficiencies in the prior art.

### SUMMARY OF THE INVENTION

To achieve the foregoing and other objects, and in accordance with the purposes of the present invention, as embodied and broadly described herein, the present invention provides a method for plasma etching a semiconductor feature to improve an etching profile.

In a first embodiment, the method includes providing a semiconductor wafer including a photoresist layer having a photolithographically patterned portion for etching a feature through a thickness portion of at least one underlying dielectric layer; and, plasma treating the photoresist layer with a carbon monoxide (CO) containing plasma to induce a polymeric cross-linking reaction at the photoresist layer surface to decrease a photoresist layer etching rate in a subsequent etching process; and, etching said feature through the thickness portion to maintain a width dimension of said feature including the photolithographically patterned portion within a pre-determined dimensional variation.

These and other embodiments, aspects and features of the invention will become better understood from a detailed description of the preferred embodiments of the invention which are described in conjunction with the accompanying drawings.

### BRIEF DESCRIPTION OF THE DRAWINGS

FIG. 1 is a cross sectional side views of an exemplary dual damascene structure at a stage in manufacture according to the prior art.

FIGS. 2A-2F are cross sectional side views of an exemplary dual damascene structure at stages in a manufacturing process according to an embodiment of the present invention.

FIG. 3 is a process flow diagram including several embodiments of the present invention.

### DETAILED DESCRIPTION OF THE PREFERRED EMBODIMENTS

Although the method of the present invention is explained by exemplary reference the formation of a via-first method of formation of a dual damascene structure in a multi-level semiconductor device, it will be appreciated that the method of the present invention including the carbon monoxide (CO) containing plasma treatment process is equally applicable to the formation of any semiconductor feature where residual photoresist or polymeric residue remains on features following a photolithographic patterning process where such residue is advantageously removed according to the carbon monoxide (CO) containing plasma treatment process while maintaining an overlying photoresist layer profile. In addition, the method of the present invention is particularly advantageous for, but need not be limited to the removal of photoresist residue within a semiconductor feature. For example, the CO containing plasma treatment of the present invention may advantageously used in any semiconductor feature anisotropic etching process where an etching rate of an overlying photoresist layer is advantageously reduced to maintain a photoresist pattern critical dimension and profile.

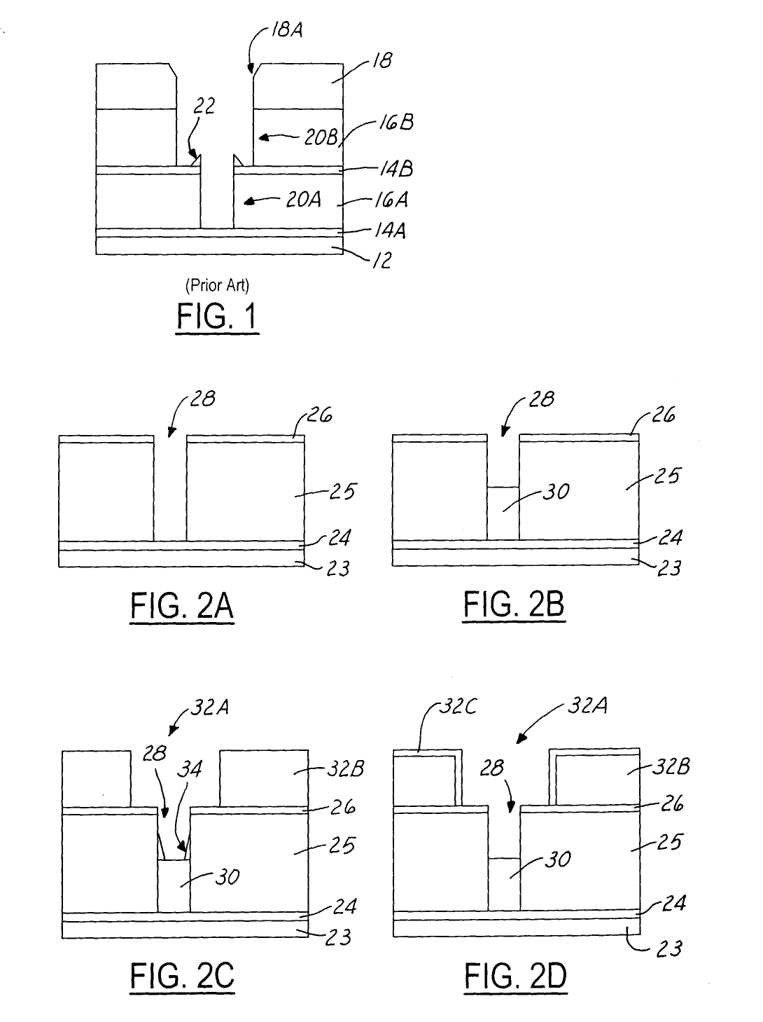

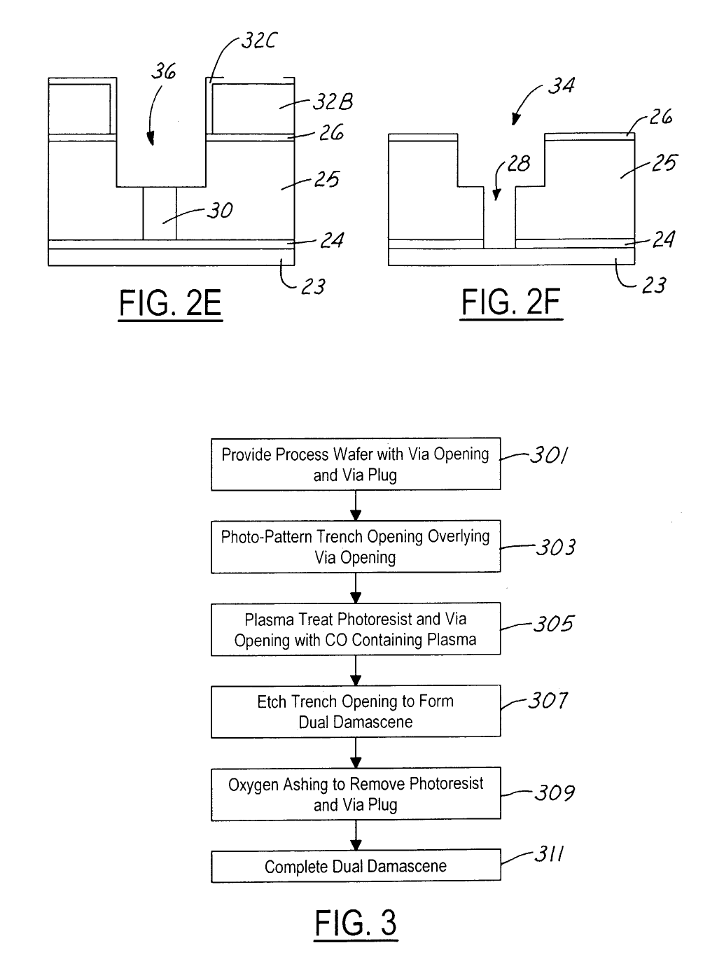

For example, in an exemplary embodiment, referring to FIGS. 2A-2F, are shown cross sectional side views of a portion of a multi-level semiconductor device formed on a semiconductor process wafer at stages in a dual damascene manufacturing process. Referring to FIG. 2A is shown a conductive region 23, having an overlying etch stop layer 24, for example, silicon carbide (e.g., SiC), or silicon nitride (e.g., Si₃N₄), formed by a conventional chemical vapor deposition (CVD) process including for example, LPCVD (low pressure CVD), having a thickness of about 300 Angstroms to about 700 Angstroms. If the etch stop layer 24 is formed of silicon carbide, preferably an overlying silicon dioxide capping layer (not shown) is formed of TEOS (tetra-ethyl-ortho-silicate) precursor according to a conventional plasma enhanced CVD (PECVD) process.

Still referring to FIG. 2A, formed over etching stop layer 24 is formed a dielectric insulating layer 25, also referred to as an inter-metal dielectric (IMD) layer formed of, for example, a carbon doped silicon dioxide, also referred to as organo silicate glass (OSG) and C-oxide. Several commercially available formulations are available for producing the low-k carbon doped oxide, for example, known as SILK™ and BLACK DIAMOND™ according to conventional PECVD processes. Typically, the IMD layer is formed having a thickness of about 6000 to about 8000 Angstroms.

Alternatively, the IMD layer may be formed of fluorine doped silicon oxide also referred to as fluorinated silicate glass (FSG). For example, if FSG is used as the IMD layer, preferably two IMD layers are formed, one IMD layer for containing the via opening portion and an overlying IMD layer separated from the first IMD layer by a second etch stop layer for containing the trench opening portion of the dual damascene structure. In this case, each of the IMD layers are typically formed having a thickness of about 4000 to 6000 Angstroms and the first (e.g., 22) and second (not shown) etch stop layers formed of silicon nitride (Si₃N₄).

Still referring to FIG. 2A, in the exemplary embodiment, the dual damascene structure is formed in a single IMD layer 25, for example using organo silicate glass (OSG). Following deposition of the IMD layer 25, a dielectric anti-reflectance coating (DARC) layer 26 is formed, for example, a single layer of silicon oxynitride (e.g., SiON), functioning as both an etch stop and a DARC layer. The etch stop/DARC layer 26 is deposited, for example, by an LPCVD process, having a thickness of about 1000 Angstroms to about 1400 Angstroms. It will be appreciated that both etch stop layer and DARC layer may be formed, for example including a silicon nitride (Si₃N₄) etch stop layer and an overlying SiON DARC layer. The DARC layer is also referred to as bottom anti-reflectance coating (BARC) and is formed to reduce undesired light reflections from an underlying IMD layer or etch stop layer surface during a photolithographic patterning process.

Still referring to FIG. 2A, a conventional photolithographic patterning process followed by a conventional reactive ion etching (RIE) step is carried out to form via opening 28. For example, the anisotropic etching step includes sequential etching steps including conventional plasma etching chemistries formed of combinations of gases including hydrofluorocarbons, fluorocarbons, nitrogen, and oxygen to sequentially etch through a thickness of the etch stop/DARC layer 26, the IMD layer 25, and partially through a thickness of the etch stop layer 24.

Referring to FIG. 2B, following anisotropically etching via opening 28, a resinous material layer, such as an I-line photoresist, or novolac (novolak) resin, optionally including a photoactive sensitizer such as diazonapthoquinone (DNQ), is blanket deposited by a spin-coating process to fill via opening 28 followed a thermal and/or ultraviolet radiative curing process to initiate further polymeric cross linking reactions and/or to drive off solvents. For example, the thermal curing process is carried out from about 90° C. to about 140° C. and the radiative curing process is carried out with ultraviolet light including wavelengths of less than about 400 nm. A conventional plasma etching chemistry including oxygen is then used to etchback the resinous material layer to form via plug 30 filling at least a portion of via opening 28 depth, for example from about ⅓ to about ¾, more preferably about ½ of the via opening 28 depth. Preferably, the resinous layer is etched back such that the via plug is formed to fill the via to a level about where a subsequently formed overlying trench line depth reaches the via plug level. The via plug 30 serves to protect the via sidewalls during a subsequent trench opening etching process and provides an etching endpoint detection means for the trench line etching process where the trench portion is formed in the IMD layer 25 overlying one or more via openings e.g., via opening 28.

Referring to FIG. 1C, a second conventional photolithographic patterning process, for example using a DUV photoresist, is then carried out to pattern a trench opening etching pattern 32A in photoresist layer 32B overlying and encompassing via opening 28. It will be appreciated that the trench opening pattern may encompass more than one via opening, e.g., via opening 28. Following patterning trench opening etching pattern 32A, photoresist residue e.g., at 34 remains along the via opening sidewalls above the via plug.

Referring to FIG. 2D, according to an aspect of the present invention, following formation of the trench opening etching pattern 32A in photoresist layer 32B but prior to anisotropically etching the trench opening, a carbon monoxide (CO) containing plasma treatment process is carried out to remove photoresist residue e.g., 34 along the via opening 28 sidewalls and to form a polymer cross-linked surface portion 32C of the photoresist layer 32B to reduce an etching rate of the photoresist layer. According to the present invention, the CO containing plasma treatment process includes CO and a diluent gas, for example, nitrogen (N2), helium (He), argon (Ar), or a combination thereof. More preferably, the diluent gas is nitrogen (N₂) as N₂ together with CO has been found to give superior residue removal while minimizing photoresist layer 32B etching. It will be appreciated that the diluent gas participates in plasma species bombardment and etching of the target etching surface. Preferably the CO containing plasma treatment includes plasma source gas mixture of diluent gas and CO gas supplied to maintain a plasma. It will be appreciated that the diluent gas and CO may be individually fed to the plasma reactor volume to form a plasma source gas volumetric mixture or the diluent gas and the CO may be pre-mixed at the preferred volumetric ratios. Preferably the CO containing plasma treatment includes a plasma source gas mixture of diluent gas and CO including a volumetric percent ratio of diluent gas to CO of about 30:70 to about 70:30, more preferably about 50:50 volume percent ratio to make up 100 volume percent with respect to a plasma source gas mixture volume.

For example in a preferred embodiment, the plasma source gas mixture is formed by individually feeding (supplying) plasma source gases to the plasma reactor where N₂ and CO are supplied at a total plasma operating pressure of about 20 milliTorr to about 50 milliTorr, more preferably about 30 milliTorr. The CO containing plasma treatment is preferably carried out at an RF power of about 1000 Watts to about 1500 Watts. CO containing plasma treatment is preferably carried out for a period of about 20 seconds to about 40 seconds. In addition, the temperature of the process wafer is about 300° C. to about 400° C.

Still referring to FIG. 1D, it has been found that the CO containing plasma treatment of the present invention has the advantageous property of not only effectively removing photoresist residue along the via opening sidewalls above the via plug but the added and unexpected benefit that a cross-linked polymer is formed at the photoresist layer surface by a chemical reaction between CO and the photoresist in a surface portion e.g., 32C of the photoresist layer. It has been found that the photoresist layer thereby beneficially exhibits an increased etching resistance (lower etching rate) during a subsequent trench etching process increasing the selectivity of the trench etching process. Consequently, photoresist etching is reduced during trench etching of the IMD layer which reduces a widening the trench etching pattern in the upper portion of the photoresist layer 32B due to photoresist sidewall etching. As a result, critical dimensions (CD) or dimensional variations of the trench photoresist pattern are maintained within an etching bias window thereby allowing the formation of more vertical and dimensionally consistent trench profiles during the trench etching process. For example, it has been found that enlargement of the trench opening pattern at the upper portion of the photoresist layer can be reduced from about 25 percent to about 40 percent using a CO containing plasma treatment according to preferred embodiments thereby improving a trench etching profile. Moreover, it has been found that the CO containing plasma treatment effectively removes photoresist residue within the via opening consequently leading to the absence of a via fence formed of etching resistant residues protruding above the trench bottom portion following trench etching.

Preferably, the etching process is carried out including a dual RF power source, for example a dual plasma source (DPS) or an inductively coupled plasma (ICP) where the RF power source is decoupled from a bias generating RF power source. For example, preferably the trench etching process is carried out in-situ following the CO containing plasma treatment process of the present invention. For example, during the CO containing plasma treatment an RF bias is preferably not applied to reduce critical dimension bias in the photoresist layer. In the subsequent trench etching process an RF bias may optionally be applied to control an ion bombardment energy and to improve a trench opening profile by obtaining more vertical trench sidewalls.

Referring to FIG. 1E, following the CO containing plasma treatment, the trench etching process is carried to form trench 36 in a multi-step plasma etching process including a first plasma etching process to etch through the etch stop/DARC layer 26 according to a conventional plasma etch process. In a second step, the IMD layer 25, is etched through a thickness to about the level of the via plugs to include etching a portion of the via plugs. Preferably, the plasma etch conditions include a plasma source gas mixture of CF₄, N₂, and Ar including a volumetric ratio CF₄ to N₂ of about 0.6 to 1 to about 0.9 to 1, more preferably about 0.8 to 1 to make up about a 70 to about 90 volume percent with respect to a plasma source mixture gas volume with a remaining plasma source gas volume made up of an inert gas, preferably argon. The IMD layer etching process is preferably carried out at a pressure of about 60 milliTorr to about 90 milliTorr, more preferably about 80 milliTorr and an RF power of about 750 Watts to about 850 Watts where no RF bias power is supplied to the process wafer backside.

Referring to FIG. 1F, following the trench etching process a conventional oxygen ashing process is carried out to remove the photoresist layer 32B and the remaining via plug 30. A conventional RIE etching process is then used to etch through a remaining portion of the etch stop layer 24 to reveal the conductive layer 23.

Although not shown, the dual damascene structure is then completed according to conventional processes. For example, the dual damascene opening is filled with metal, for example, copper according to an electrodeposition process followed by a CMP process to remove excess copper above the trench opening to complete the formation of a dual damascene. Prior to electrodeposition of copper, a barrier/adhesion layer of, for example, tantalum nitride, is blanket deposited to line the dual damascene structure, followed by deposition of a copper seed layer to provide an electrodeposition surface. During the subsequent CMP process the process surface is planarized above the trench line opening to complete the formation of the dual damascene structure.

Referring to FIG. 3 is shown a process flow diagram including several embodiments of the present invention. In process 301, a semiconductor wafer including a process wafer having a via opening and via plug at least partially filling the via opening is provided. In process 303, a photoresist layer is deposited and photolithographically patterned to form a trench opening etching pattern overlying and encompassing the via opening. In process 305, prior to etching the trench opening a CO containing plasma treatment is carried out to remove residual photoresist from the via sidewalls and to form a CO containing polymer cross-linked surface in the photoresist layer. In process 307, an in-situ trench etching process is then carried out to etch the trench opening to form a dual damascene structure while avoiding the formation of an etching resistant residue, i.e., a via fence around the via opening. In process 309, an oxygen ashing process is carried out to remove the photoresist layer and the via plug. In process 311, several conventional processes are carried out to complete the dual damascene including exposing the underlying conductive layer, depositing a barrier/adhesion layer, depositing a metal filling layer and planarizing (e.g., CMP) the process surface above the trench level.

The preferred embodiments, aspects, and features of the invention having been described, it will be apparent to those skilled in the art that numerous variations, modifications, and substitutions may be made without departing from the spirit of the invention as disclosed and further claimed below.

What is claimed is:

1. A method for plasma etching a semiconductor feature to improve an etching profile comprising the steps of:
providing a semiconductor wafer comprising a photoresist layer having a photolithographically patterned portion for etching a feature through a thickness portion of at least one underlying dielectric layer; and,
plasma treating the photoresist layer with a carbon monoxide (CO) containing plasma to induce a polymeric cross-linking reaction at the photoresist layer surface to decrease a photoresist layer etching rate in a subsequent etching process; and,
etching said feature through the thickness portion to maintain a width dimension of said feature including the photolithographically patterned portion within a pre-determined dimensional variation.

2. The method of claim 1, wherein the semiconductor wafer further comprises a first feature opening etched though a first thickness portion of at least one dielectric insulating layer.

3. The method of claim 2, wherein said feature is formed overlying an encompassing said first feature.

4. (not entered)

5. The method of claim 4, wherein said feature is a trench opening and said first feature opening is a via opening comprising a dual damascene structure.

6. The method of claim 5, wherein the step of plasma treating further removes photoresist residue along a sidewall of said via opening above a resinous via plug filling a portion of said via opening.

7. The method of claim 6, wherein following the step of etching, said via opening is substantially free of an etching resistant etching residue protruding above a bottom portion of the trench opening.

8. The method of claim 2, wherein the at least one dielectric insulating layer comprises a member selected from the group consisting of organo silicate glass (OSG) and fluorinated silicate glass (FSG).

9. The method of claim 1, wherein said CO containing plasma is formed by a plasma source gas mixture comprising carbon monoxide and at least one diluent gas selected from the group consisting of helium, argon, nitrogen, and oxygen.

10. The method of claim 1, wherein carbon monoxide in said CO containing plasma chemically reacts with the photoresist layer to reduce an etching rate of the photoresist layer.

11. The method of claim 9, wherein said plasma source gas mixture comprises a volumetric percent ratio of carbon monoxide to diluent gas of about 30 to 70 volume percent to about 70 to 30 volume percent with respect to said plasma source gas mixture volume.

12. The method of claim 1, wherein the step of etching said feature is carried out in-situ following the step of plasma treating.

13. A method for plasma etching a dual damascene structure to improve an etching profile and critical dimension etching bias comprising the steps of:
providing a semiconductor wafer comprising a via opening extending though a thickness portion of at least one dielectric insulating layer and having a photolithographically patterned overlying photoresist layer for etching a trench opening overlying the via opening;
plasma treating the photoresist layer with a carbon monoxide (CO) containing plasma to remove photoresist residue along a portion of the via opening sidewall; and,
etching the trench opening in-situ overlying and at least partially encompassing the via opening according to a reactive ion etch (RIE) process to remain within a critical dimension (CD) etching bias window.

14. The method of claim 13 wherein the step of plasma treating induces a polymeric cross-linking reaction at the photoresist layer surface to decrease a photoresist layer etching rate in the step of etching the trench opening to remain within a critical dimension (CD) etching bias window.

15. The method of claim 13, wherein the via opening comprises above a resinous via plug filling a portion of the via opening.

16. The method of claim 13, wherein following the step of etching, the via opening at the trench level is substantially free of an etching resistant etching residue.

17. The method of claim 13, wherein the at least one dielectric insulating layer comprises a member selected from the group consisting of organo silicate glass (OSG) and fluorinated silicate glass (FSG).

18. The method of claim 1, wherein the CO containing plasma is formed by a plasma source gas mixture comprising carbon monoxide and at least one diluent gas selected from the group consisting of helium, argon, nitrogen, and oxygen.

19. The method of claim 18, wherein the plasma source gas mixture comprises a volumetric percent ratio of carbon monoxide to diluent gas of about 30 to 70 volume percent to about 70 to 30 volume percent with respect to the plasma source gas mixture volume.

20. The method of claim 1, wherein the step of etching the trench opening is carried out in-situ following the step of plasma treating.
